(19) United States
(12) Patent Application Publication
(10) Pub. No.: US 2005/0077534 A1
(43) Pub. Date: Apr. 14, 2005

(54) Light-emitting diode and method of manufacturing the light-emitting diode

(76) Inventors: Bing Lin Yang, Tokyo (JP); Masahiko Koshihara, Gyoda-shi (JP)

Correspondence Address: BIRCH STEWART KOLASCH & BIRCH, PO BOX 747, FALLS CHURCH, VA, 22040-0747, US

(21) Appl. No.: 10/681,114

(22) Filed: Oct. 9, 2003

(51) Int. Cl. H01L 33/00; H01L 21/00

(52) U.S. Cl. 257/99; 438/22; 257/100; 257/98; 438/25

(57) ABSTRACT

A light-emitting diode has a case having a concave portion, a reflection mirror obtained by forming metal on the concave portion, and a lead to one end of which a light-emitting element is attached. A cavity including the concave portion of the case is filled with an accelerated curing epoxy resin. The epoxy resin is cured so that the epoxy resin, the reflection mirror and the case are formed into a sandwich structure. With such a structure, a light-emitting diode free of wrinkles and cracks on the reflection mirror is provided. Further, at the time of handling or transportation, the reflection mirror is not damaged. Moreover, during reflow soldering, at the time of solder-mounting the light-emitting diode to a printed circuit board, thermal deformation, such as wrinkling and cracking of the reflection mirror is completely prevented.

### BACKGROUND OF THE INVENTION

1. Field of the Invention

The present invention relates to a light-emitting diode having a reflection mirror filled with an accelerated curing epoxy resin and a method of manufacturing the light-emitting diode.

2. Description of the prior art

Structures of light-emitting diodes for effectively radiating light emitted in a forward direction from a light-emitting element via a metallic-reflection mirror are disclosed in many prior art publications. These prior art light-emitting diode structures are divided into three types: in a first type, a metallic-reflection mirror is vapor-deposited on an outside surface of a case; in a second type, the metallic-reflection mirror is vapor-deposited on an inside surface of the case; and in a third type, a pre-fabricated metallic plate reflection mirror is used.

As examples in which the metallic-reflection mirror is provided on the outside surface of the case, light-emitting diodes are disclosed in Japan Laid-Open Patent Publication No. Sho. 49-82290 (1974) and Japan Laid-Open No. Sho. 58-82290 (1983). Such a light-emitting diode is shown in FIG. 6. As shown there, a light-emitting element 61 is attached to a lead 62a by a conductive resin 63 and is electrically connected with a lead 62b via a gold wire 64. The light-emitting element 61 which is attached to the leads 62a and 62b is put into a hemispherical or parabolic shaped die, and the leads 62a and 62b and the light-emitting element 61 are integrally molded by transfer molding in a light-transmissive resin 65. A surface coating is to applied to an outer surface of a convex portion of the hemispherical or parabolic shape by metal vapor-deposition, plating, or the like, so that a concave reflection mirror 66 is formed, and an overcoat layer 67 is applied to protect the concave reflection mirror 66. The concave reflection mirror 66 reflects light radiated by the light-emitting element 61 and radiates it from a plane 68. With such a structure, almost all of the light radiated from the light-emitting element 61 is reflected from the reflection mirror 66 and is radiated from the plane 68 outside of the light-emitting diode.

As examples in which the metallic-reflection mirror is provided inside the case, light-emitting diodes are disclosed in Japan Laid-Open Patent Publication No. Sho. 62-269984 (1987), Japan Laid-Open Patent Publication No. Hei. 01-143366, and Japan Laid-Open Utility Model Patent Publication No. Sho. 55-113570 (1980). As shown in FIG. 7, in such a light-emitting diode, a light-emitting element 73 is positioned at the focal point of a reflection mirror 72 produced by vapor-depositing aluminum or silver or plating a metal layer on a concave portion of a case 71. This light-emitting element 73 is similar to the first example in that one end of the light-emitting element 73 is attached to a lead 74a using a conductive adhesive and another end is electrically connected with a lead 74b via a gold wire 75.

In these light-emitting diodes, first, aluminum or silver is vapor-deposited or the metal layer 72 is plated on the concave portion of the case 71. Thereafter, the leads 74a and 74b are inserted into the case 71, and one end of the light-emitting element 73 is attached on the lead 74a using a conductive adhesive, and another end is electrically connected with the lead 74b via the gold wire 75.

Thereafter, after the concave portion of the reflection mirror 72 is potted in a transparent epoxy resin 76 (not shown in FIG. 7), the light-emitting element is fixed in position by heat-curing. In this kind of the light-emitting diode, when the reflection mirror 72 and the light-emitting element 73 are filled with the transparent epoxy resin 76, optical positional relationships become highly precise, so that a light-emitting diode having an improved optical characteristic can be produced. Moreover, since potting is used, the light-emitting diode can be produced with a smaller number of manufacturing steps.

Further, examples of light-emitting diodes using a pre-fabricated metallic-reflection mirror are disclosed in Japan Laid-Open Patent Publication No. Sho. 55-118681 (1980) and in U.S. Published patent application No. 2001/0024087. As shown in FIG. 8, in such a light-emitting diode, aluminum or silver is vapor-deposited or a metal layer is plated on a concave portion of a reflection mirror 85 made of a metallic plate, and a light-emitting element 81 is positioned at the focal point of the reflection mirror 85 made of the metallic plate.

This light-emitting diode is similar to the first example in that one end of the light-emitting element 81 is attached to a lead 82a using a conductive adhesive or the like and another end is electrically connected with a lead 82b via a gold wire 83.

In these light-emitting diodes, the leads 82a and 82b, the light-emitting element 81, the gold wire 83, and the reflection mirror 85 made of the metallic plate produced by vapor depositing aluminum or silver or plating a metal layer on the concave portion are integrally fabricated by transfer molding using the transparent epoxy resin 84 and are heated to cure the epoxy. In such a light-emitting diode, since the reflection mirror 85 and the light-emitting element 81 are filled with the transparent epoxy resin 84, optical positional relationships become highly precise, and a light-emitting diode with improved optical characteristics is produced.

However, in the light-emitting diode having the structure of the first examples, where the metallic-reflection mirror is located on the outside of the case, in packing, such as boxing, the reflection mirror is exposed, although a protective layer is provided by a hard coating. When the light-emitting diode is mounted or handled, cracks occasionally occur on the reflection mirror through the protective (overcoat) layer due to contact between reflection mirrors and between the reflection mirror and a lead end. The cracks cause a problem by lowering reflecting performance of the reflection mirror, early deterioration of the reflection mirror, and the like.

In general, when an electronic part is mounted onto a printed circuit board, the entire printed circuit board is passed through a reflow furnace at a temperature of about 250 degrees Celsius to solder the parts to the printed circuit board. When the light-emitting diode having the metallic-reflection mirror is mounted on the printed circuit board and the printed circuit board is passed through the reflow furnace, the temperature of the entire printed circuit board, including the light-emitting diode, rises to about 250 degrees Celsius. For this reason, wrinkles and cracks occur on the reflection mirror due to a difference between the thermal expansion coefficient of the transparent epoxy resin and the thermal expansion coefficient of the silver layer or aluminum layer composing the reflection mirror. Thus a problem occurs in that reflectance of the reflection mirror is lowered and the optical characteristics are adversely affected.

Further, at the time of transporting the light-emitting diode, it should be packed by a special packing method so that the reflection mirror of each light-emitting diode is not cracked due to vibration.

In addition, in the light-emitting diode having a structure integrally fabricated using only an epoxy resin, like the prior art, when a lead which protrudes from the light-emitting diode is bent at the time of mounting the light-emitting diode on a circuit board, a stress is unusually applied to an epoxy resin end face, so cracking may occur at the lead portion of the epoxy resin.

Meanwhile, in the second examples in which the metallic-reflection mirror is inside the case, the concave portion of the concave reflection mirror is filled with transparent epoxy resin by potting, so that the light-emitting element and the concave reflection mirror are fixed. However, when the transparent epoxy resin hardens and shrinks, wrinkles and cracks occasionally occur on the concave reflection mirror due to the difference in the thermal expansion coefficients of the transparent epoxy resin and silver or aluminum of the concave reflecting mirror. When the wrinkles and the cracks are conspicuous, the concave reflection mirror peels off and is dispersed as a chip within the epoxy resin. In such a case, the reflectance is lowered and the optical characteristics are deteriorated as mentioned above, thereby causing a significant technical problem. For this reason, from a practical standpoint, the reflecting characteristic is secured not by using metal, but by using a white ABS resin or alike material with high reflectance as the concave reflection mirror. However, presently insufficient reflectance is obtained from these materials.

In the third examples, using the pre-fabricated metallic-reflection mirror, the light-emitting element 81 and the reflection mirror 85 are integrally fabricated using a transparent epoxy resin, so that the light-emitting element and the concave reflection mirror are fixed. However, in the third example, since the reflection mirror 85 is manufactured using an additional step and is unified with the light-emitting element using the transparent epoxy resin that has to be cured, the number of process steps is increased, and thus the price of the light-emitting diode increases.

### SUMMARY OF THE INVENTION

The present invention has been devised in order to solve the problems described above. The invention provides a light-emitting diode having a structure in which a light-emitting element and a reflection mirror are unified by a transparent epoxy resin and in which wrinkles or cracks do not occur in the reflection mirror at the time of manufacturing. According to this invention, no special packing is necessary at the time of transportation, handling is easy, and no wrinkles or cracks occur on the reflection mirror even when the light-emitting diode is passed through a high-temperature atmosphere of a reflow furnace.

In order to solve these problems, a light-emitting diode of the present invention, includes a case having a concave portion, a metal reflection mirror on the concave portion, and a lead, with the light-emitting element attached to an end of the lead. The case includes a cavity having the concave portion that is filled with an accelerated curing epoxy resin. The epoxy resin is cured so that the epoxy resin, the reflection mirror, and the case form a sandwich structure. Since the epoxy resin is cured slowly while the sandwich structure is held, this structure has an advantage that wrinkles or cracks do not occur on the reflection mirror at the time of completion of the curing. Furthermore, the light-emitting diode can be obtained by potting method at lower cost than transfer molding.

Preferably, in the assembly process, the lead is fitted into a groove on an upper end face of the case and the case is filled with the accelerated curing epoxy resin up to the upper end face of the case. With such a structure, since the lead, the light-emitting element, and the reflection mirror are integrally fixed, the light-emitting diode has optical positional relationships that are highly precise.

Preferably, the accelerated curing epoxy resin is a novolak.

More preferably, the light-emitting diode of the present invention further includes a frame put on the upper end face of the case. The frame has a protrusion for filling a gap between an upper surface of the lead fitted into the groove and the frame. When the frame is put on the case, the gap is filled by the protrusion. Such a structure has the advantages that the epoxy resin is prevented from leaking from the groove at the time of curing, and, simultaneously, that the structure resists bending of the lead after the epoxy is cured.

More preferably, the case of the light-emitting diode according to the present invention is made of a heat-resistant resin such as a polycarbonate resin, a PPS alloy resin, or a polyether ether ketone resin. Moreover, the case of the light-emitting diode according to the present invention can be a resin containing glass fibers. The use of the heat-resistant resin or the resin containing glass fibers is advantageous to provide the light-emitting diode having high heat resistance in which wrinkles or cracks do not occur on the surface of the reflection mirror due to high heat during reflow soldering.

More preferably, the case of the light-emitting diode according to the present invention is made of a resin containing glass fibers, and after a base layer of a heat-resistant epoxy resin is formed on a surface of the concave portion, a metallic-reflection mirror is formed on the base layer. With such a structure, the light-emitting diode with excellent reflectance and which is to heat is obtained.

Further, according to another aspect of the invention, the present invention provides a light-emitting diode manufacturing method including forming a case having a concave portion, forming a reflection mirror obtained by forming a metal layer on the concave portion, and forming a lead to which a light-emitting element is attached. This light-emitting diode manufacturing method includes steps of filling a cavity of the concave portion of the case with an accelerated curing epoxy resin, and curing the epoxy resin. The cured epoxy resin, the reflection mirror, and the case form a sandwich structure. In this invention, since the accelerated curing epoxy resin is cured slowly while the sandwich structure is being held, wrinkles and cracks do not occur on the reflection mirror at the time of completion of the curing.

Preferably, the steps of filling the cavity includes fitting the lead into a groove on an upper end face of the case and filling the case with the accelerated curing epoxy resin up to the upper end face.

In addition, preferably, filling the case with the accelerated curing epoxy resin in the light-emitting diode manufacturing method according to the present invention further includes fitting the lead into a groove on an upper end face of the case, putting a frame covering the upper end face of the case and having a protrusion on a portion corresponding to the groove of the case, on the case, and filling the case with the accelerated curing epoxy resin up to the upper end face of the case.

Further preferably, in forming the case having the concave portion according to the present invention, a heat-resistant resin such as a polycarbonate resin, a PPS alloy resin, or a polyether ether ketone resin is used as the material of the case. The resin may contain glass fibers.

Preferably forming the case having the concave portion and filled with the resin containing glass fibers further includes steps of forming a base layer of a heat-resistant epoxy resin on the surface of the concave portion and forming a metal reflection mirror on the base layer.

### BRIEF DESCRIPTION OF THE DRAWINGS

FIG. 1 is a perspective view of a light-emitting element, which is mounted on a lead, as a light-emitting diode according to the present invention.

FIG. 2A is a perspective view of a case used for the light-emitting diode of the present invention.

FIG. 2B is a front elevational view of the case.

FIG. 3 is an exploded perspective view showing a relationship between the case and the lead used for the light-emitting diode of the present invention.

FIG. 4 is a perspective view of the light-emitting diode when the lead is fitted into a groove of the case according to the present invention.

FIG. 5 is an exploded perspective view showing a state when the lead is fitted into the case and a frame is put on the case according to the present invention.

FIG. 6 is a cross sectional view of a first conventional reflection type light-emitting diode in which a light-emitting element and a hemisphere are unified by an epoxy resin and a reflection mirror is formed on an outside of the hemisphere.

FIG. 7 is a cross sectional view of a second conventional reflection type light-emitting diode in which a light-emitting element and a reflection mirror on a concave portion of a case are unified by an epoxy resin.

FIG. 8 is a cross section structural diagram of a third conventional reflection type light-emitting diode using a pre-fabricated reflection mirror.

### DETAILED DESCRIPTION OF THE PREFERRED EMBODIMENTS

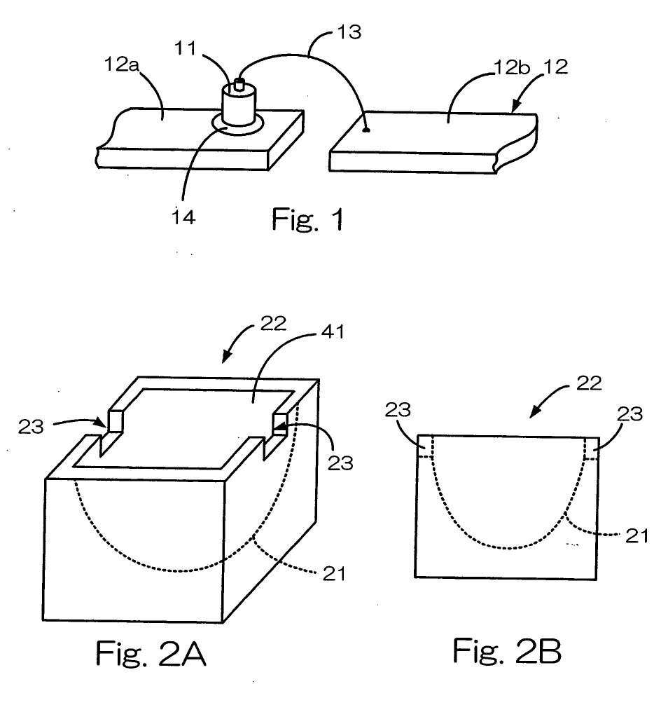

There will be explained below embodiments of the present invention with reference to FIGS. 1 through 5.

FIG. 1 is a perspective view showing a light-emitting element mounted on a lead frame 12 used for a light-emitting diode according to the present invention which is molded by potting method. One end of the light-emitting element 11 is fixed to a lead 12a via a conductive resin 14, whereas another end of the light-emitting element 11 is electrically connected to a lead 12b via a gold wire 13. The lead frame 12 on which the light-emitting element is mounted is prepared for the light-emitting diode.

FIGS. 2A and 2B show a case used for the light-emitting diode of the present invention. As shown in FIGS. 2A and 2B, the case 22, which is entirely made of a resin and the inside of which has a cavity or a concave portion 41, is prepared, and a concave reflection mirror 21, produced by vapor-deposition of aluminum or silver or by plating a metal layer, is formed on a concave surface of the concave portion 41. In order to fit the leads (12a, 12b) into the case 22, grooves 23, which match the lead dimension, are formed on opposed upper end portions of the case 22.

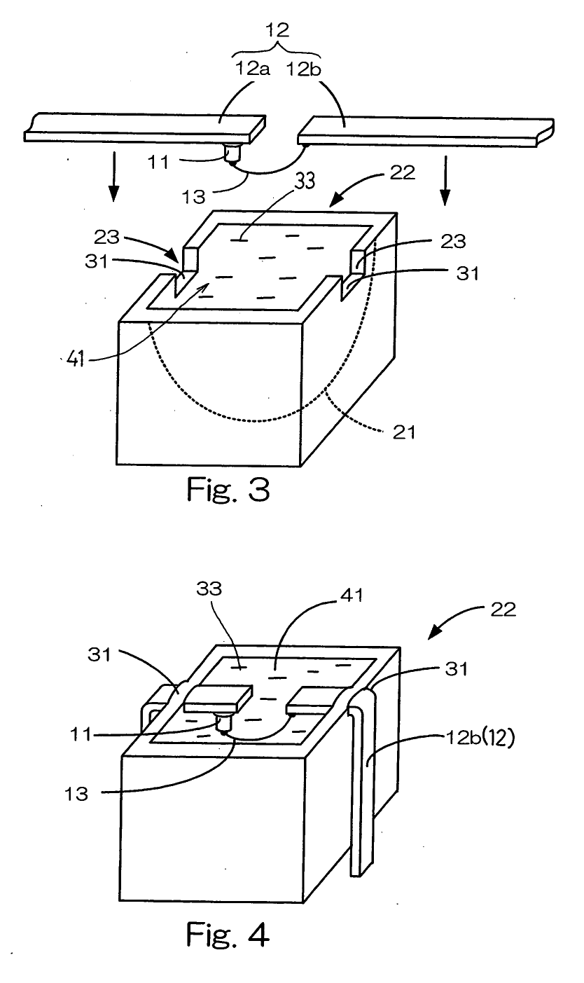

FIG. 3 shows a relationship between the case and the lead frame used for the light-emitting diode of the present invention. As shown in FIG. 3, the lead frame 12 mounted with the light-emitting element 11 is fitted into the grooves 23 of the case 22 so that the light-emitting element 11 faces the reflection mirror 21. At this time, namely, when the lead frame 12 is fitted into the grooves of the case 22, a small amount of a photo curing resin or an adhesive resin 31 is dropped onto the lead portions corresponding to the grooves from a dispenser or the like before fitting of the lead frame 12, and cured so that the case 22 and the lead frame 12 are fixed to each other. Further, the resin 31 may be filled in the groove 23 up to an upper end face of the case 22 and cured to secure fitting of the lead frame 12 and prevent a leakage of resin to be filled in the cavity 41 in the subsequent process.

After the concave portion 41 of the case 22 is filled with an accelerated curing epoxy resin 33 up to an edge surface of the case 22 by potting, the resin is cured at a temperature of 80 to 130 degree Celsius. An important feature of the present invention is the use of the accelerated curing epoxy resin 33 to cure a transparent epoxy resin smoothly. In order to cure the transparent epoxy resin 33, the method in which the concave portion 41 of the case 22 is filled with an epoxy resin and a curing agent is normally used. In this method, using the curing agent, two liquids, the epoxy resin and the curing agent, are mixed in a predetermined ratio, agitated and heated, so that a chemical reaction between the two liquids is accelerated by heating and the two liquid are thermally cured. As the transparent epoxy resin used here, a bisphenol epoxy resin which is a non-accelerated curing epoxy resin is used, and a methyl-tetrahydrophthalic anhydride (Me-THPA) or the like is used as the curing agent. However, when such a curing agent is used, since the transparent epoxy resin is abruptly cured at a reaction rate of about 85%, the transparent epoxy resin abruptly contracts at a boundary between the transparent epoxy resin and the reflection mirror 21, so that the reflection mirror 21 may peel off or a wrinkle may occur on the reflection mirror 21.

On the other hand, in the method of using the accelerated curing epoxy resin 33, like the present invention, a novolak epoxy resin is used as the transparent epoxy resin 33. When this novolak epoxy resin is used, the curing proceeds gradually, with a reaction rate between about 20% and about 90%. For this reason, when the accelerated curing epoxy resin is used, since its curing speed is slow throughout the entire curing process, wrinkles or cracks do not occur on the reflection mirror at the completion of the curing.

Further, in the light-emitting diode of the present invention, since the reflection mirror 21 is completely protected against external mechanical shock or thermal shock by the case 22 made of a heat-resistant resin, cracking can be prevented from occurring on the reflection mirror at the time of handling and transportation.

In addition, in the reflow furnace, at the time of solder-mounting, when the light-emitting diode passes through the reflow furnace, the temperature of the entire printed circuit board, including the light-emitting diode, rises to about 250 degrees Celsius. However, in the light-emitting diode of the present invention, as mentioned above, since the accelerated curing epoxy resin 33 is cured so that the epoxy resin 33, the reflection mirror 21, and the case 22 form a sandwich structure, wrinkles or cracks do not occur on the reflection mirror due to a small difference between the thermal expansion coefficients of the transparent epoxy resin 33 and the silver layer or the aluminum layer of the reflection mirror 21. Thus the reflectance of the reflection mirror 21 is not lowered and the optical characteristics are not adversely affected.

FIG. 4 is a diagram showing a final structure of the light-emitting diode when the lead frame 12 is fitted into the grooves 23 (FIG. 3) of the case 22 according to the present invention. In FIG. 4, the lead frame 12 is fitted into the grooves 23 of the case 22, and after a small amount of the photo curing resin or adhesive resin 31 is dropped into the groove portions from a dispenser or the like, the groove portions are cured. Thereafter, the lead frame 12 is bent outside of the grooves 23 of the case 22, so that electric source supply terminals are produced.

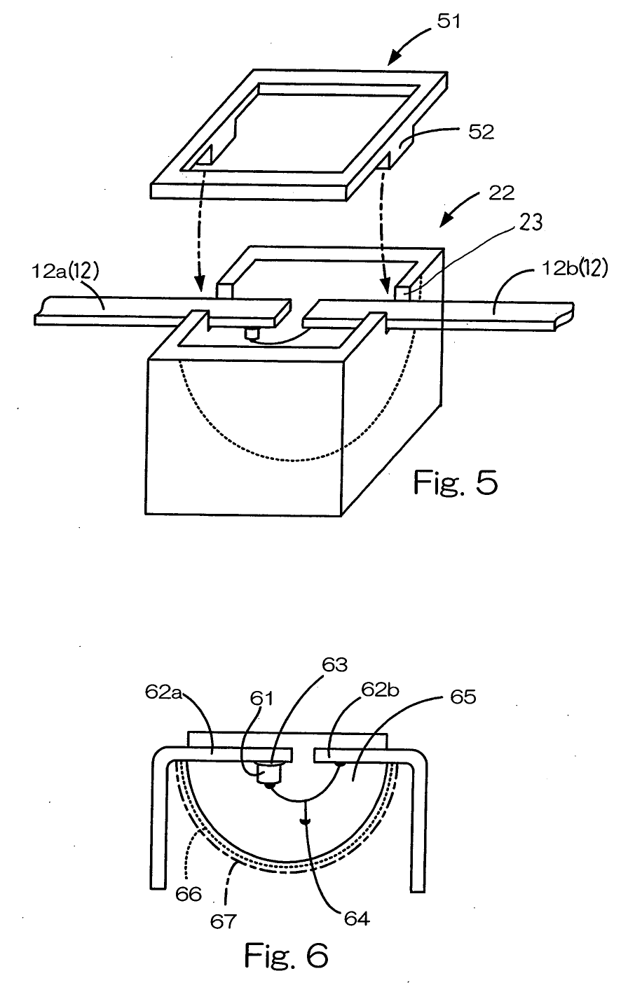

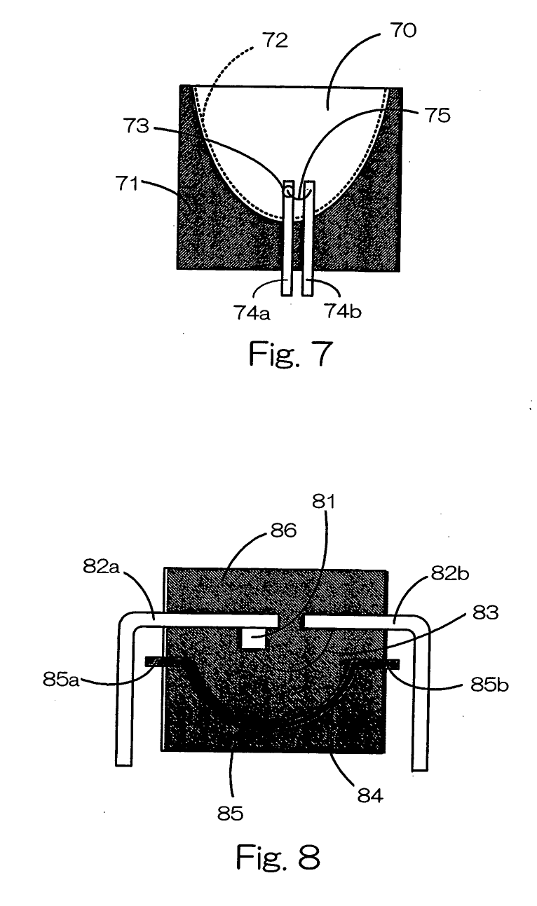

FIG. 5 shows a state when the lead frame is fitted into the case and a frame is to be placed on the case according to the present invention.

In FIG. 4, in order to prevent leakage of the resin 33 from the portions of the grooves 23 more reliably, and in order to improve strength of connecting portion with the case 22 at the time of bending the lead frame 12, as shown in FIG. 5, the frame 51, which has protrusions 52 corresponding to recesses left at the time of fitting the lead frame 12 into the grooves 23, is put on the case 22. As a result, the leakage of the resin 33 can be prevented more completely, so that the strength at the time of bending the lead frame 12 is improved. At this time, an adhesive is applied to a laminated surface between the frame 51 and the case 22, improving workability for the filling of the case with the accelerated curing epoxy resin 33.

In the above-mentioned embodiment, a polycarbonate resin is used as the material of the case 22, but a glass fiber contained resin, such as polycarbonate resin, an alloy resin composed of an Aton resin and an PPS (polyphenylene sulfide) resin, or a polyether ether ketone resin may be used, thereby increasing heat resistance. When such a resin containing glass fiber is used, the heat resistance during reflow soldering is further increased, thereby providing the light-emitting diode having high heat resistance and excellent characteristics in which a surface of the reflection mirror does not have wrinkles or cracks due to high temperature processing.

When a resin containing glass fibers is used for the case 22, after the surface of the resin containing glass fiber is coated with a low-viscosity two liquid epoxy resin or a photo curing epoxy resin to a thickness of several μm in order to secure a mirror surface on the concave portion of the case 22, a metal film is formed on the surface by a vapor-deposition, thereby producing a light-emitting diode having excellent reflectance.

1. A light-emitting diode comprising:
a case having a concave inner surface;
a metal reflection mirror on the concave inner surface; and
a lead to one end of which a light-emitting element is attached, wherein a cavity of the concave inner surface of the case is filled with an accelerated curing epoxy resin, and the reflection mirror is sandwiched between the case and said accelerated curing epoxy resin to form a sandwich structure.

2. The light-emitting diode according to claim 1, wherein the lead is fitted into a groove in an upper end face of the case and the case is filled with the accelerated curing epoxy resin up to the upper end face of the case.

3. The light-emitting diode according to claim 1, wherein the accelerated curing epoxy resin is a novolak.

4. The light-emitting diode according to claim 1, wherein the case is made of a heat-resistant resin selected from the group consisting of a polycarbonate resin, a PPS alloy resin, and a polyether ether ketone resin.

5. The light-emitting diode according to claim 4, wherein the heat-resistant resin contains glass fibers.

6. The light-emitting diode according to claim 5, wherein a base layer of the heat-resistant epoxy resin is formed on the surface of the concave inner surface, the metal reflection mirror is formed on the base layer.

7. The light-emitting diode according to claim 1, further comprising a frame on the upper end face of the case, wherein the frame has a protrusion filling a gap between an upper surface of the lead fitted into the groove and the frame.

8. A light-emitting diode manufacturing method including forming a case having a concave inner surface forming a reflection mirror by forming a metal on the concave inner surface, and forming a lead to one end of which a light-emitting element is attached, comprising steps of:
filling a cavity including the concave inner surface of the case with an accelerated curing epoxy resin; and curing the epoxy resin to sandwich the reflection mirror between the accelerated curing epoxy resin and the case to form a sandwich structure.

9. The light-emitting diode manufacturing method according to claim 8, wherein the step of filling the cavity with the accelerated curing epoxy resin includes:
fitting the lead into a groove on a upper end face of the case; and
filling the case with the accelerated curing epoxy resin up to the upper end face of the case.

10. The light-emitting diode manufacturing method according to claim 8, wherein a novolak is used as the accelerated curing epoxy resin.

11. The light-emitting diode manufacturing method according to claim 8, wherein, in forming said case having the concave inner surface, a heat-resistant resin selected from the group consisting of a polycarbonate resin, a PPS alloy resin, and a polyether ether ketone resin is used as the material of the case.

12. The light-emitting diode manufacturing method according to claim 11, wherein the heat-resistant resin contains glass fibers.

13. The light-emitting diode manufacturing method according to claim 12, further includes steps of:
forming a base layer of the heat-resistant epoxy resin on the surface of the concave inner surface, and
forming the metal reflection mirror on the base layer.

14. The light-emitting diode manufacturing method according to claim 8, wherein the step of filling the cavity includes:
fitting the lead into a groove provided on an upper end face of the case;
putting a frame covering the upper end face of the case, and having a protrusion on a portion corresponding to the groove, on the case; and
filling the case with the accelerated curing epoxy resin up to the upper end face.
